(19) United States
(12) Patent Application Publication
(10) Pub. No.: US 2012/0314113 A1
(43) Pub. Date: Dec. 13, 2012

(54) PHOTOGRAPHING APPARATUS AND ELECTRONIC DEVICE

(75) Inventor: Hun-young Ryu, Hwaseong-si (KR)

(73) Assignee: Samsung Electronics Co., Ltd., Suwon-si (KR)

(21) Appl. No.: 13/344,825

(22) Filed: Jan. 6, 2012

(30) Foreign Application Priority Data
Jun. 13, 2011 (KR) 10-2011-0057008

(51) Int. Cl. H04N 5/225; H05K 1/11

(52) U.S. Cl. 348/333.01; 361/803; 348/E05.025

(57) ABSTRACT

A photographing apparatus and an electronic device including flexible printed circuit boards (FPCBs). The photographing apparatus includes a display unit that displays an image; a manipulation unit spaced apart from the display unit; a control unit that transmits and receives signals to and from the manipulation unit and the display unit; a first FPCB having one end connected to the display unit, and another end connected to the control unit, and including an access unit on one region of the first FPCB; and a second FPCB having one end connected to the manipulation unit, and another end connected to the access unit of the first FPCB.

### CROSS-REFERENCE TO RELATED PATENT APPLICATION

This application claims the benefit of Korean Patent Application No. 10-2011-0057008, filed on Jun. 13, 2011, in the Korean Intellectual Property Office, the disclosure of which is incorporated herein in its entirety by reference.

### BACKGROUND

The present invention relates to a photographing apparatus and an electronic device, and more particularly, to a photographing apparatus and an electronic device having a simple structure and including a flexible printed circuit board (FPCB).

Currently, photographing apparatuses such as digital cameras and digital camcorders using an imaging device such as a charge coupled device (CCD) or a complementary metal-oxide semiconductor (CMOS) are popular.

A photographing apparatus such as a digital camera includes a display unit for displaying an image received from an imaging device or stored in a storing medium, and a key manipulation unit for executing various menus related to operations of the photographing apparatus, to allow a user to set a desired composition with regard to a subject to be photographed while viewing an image formed by the imaging device, or to check a captured image. The display unit or the key manipulation unit of the photographing apparatus has an individual circuit board electrically connected to a main circuit board of the photographing apparatus, and thus transmits and receives electrical signals to and from the imaging device or the storing medium. In this case, flexible printed circuit boards (FPCBs) are used to connect the individual circuit board to the main circuit board.

### SUMMARY

Various embodiments of the present invention provide a photographing apparatus and an electronic device having a compact size, a space-saving structure, a simple manufacturing process, and a low manufacturing cost by improving the structure of flexible printed circuit boards (FPCBs).

According to an embodiment of the present invention, there is provided a photographing apparatus including a display unit that displays an image; a manipulation unit spaced apart from the display unit; a control unit that transmits and receives signals to and from the manipulation unit and the display unit; a first flexible printed circuit board (FPCB) having one end connected to the display unit, and another end connected to the control unit, and including an access unit on one region of the first FPCB; and a second FPCB having one end connected to the manipulation unit, and another end connected to the access unit of the first FPCB.

The photographing apparatus may further include an imaging device for converting an optical image of a subject into an electrical signal, and the display unit may display an image formed by the imaging device.

The first FPCB may include a first wiring unit extending from the one end toward the other end to electrically connect the display unit and the control unit to each other; and a second wiring unit extending from the access unit toward the other end to electrically connect the control unit and the second FPCB to each other.

The first FPCB may include a bent part, and the access unit may be disposed on the bent part.

The access unit may be disposed on an outer corner of the bent part.

The first wiring unit may curvedly extend along an inner side of the bent part, and the second wiring unit may be formed at an outer side of the first wiring unit.

The first FPCB may include a plurality of layers, and at least a portion of the first wiring unit and the second wiring unit may be disposed on different layers.

The first FPCB may include a first connection part extending from the one end in one direction; and a second connection part extending from the other end in a direction that forms an angle with the extending direction of the first connection part, and the bent part may connect the first and second connection parts to each other.

The access unit may be a connector.

The second FPCB may include a coupling connector coupled to the connector.

The access unit may include a pad formed on the one end of the second wiring unit; and an access layer coated on the pad.

The access layer may be formed of solder or a conductive adhesive. A number of wirings formed on the first FPCB may be greater than a number of wirings formed on the second FPCB.

According to another embodiment of the present invention, there is provided an electronic device including a first module; a second module spaced apart from the first module; a third module that transmits and receives signals to and from the first and second modules; a first flexible printed circuit board (FPCB) having one end connected to the first module, and another end connected to the third module, and including an access unit on one region of the first FPCB; and a second FPCB having one end connected to the second module, and another end connected to the access unit of the first FPCB.

A number of wirings formed on the first FPCB may be greater than a number of wirings formed on the second FPCB.

The first FPCB may include a bent part, and the access unit may be disposed on the bent part.

The access unit may be disposed on an outer corner of the bent part.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram showing elements of a photographing apparatus according to an embodiment of the present invention;

FIG. 2 is a perspective view showing an exterior of a photographing apparatus according to an embodiment of the present invention;

FIG. 3 is a partially exploded perspective view of the photographing apparatus illustrated in FIG. 2;

FIG. 4 is a plan view showing the structure of first and second flexible printed circuit boards (FPCBs) of the photographing apparatus illustrated in FIG. 3; and

FIG. 5 is a plan view showing a modified example of the first and second FPCBs illustrated in FIG. 4.

### DETAILED DESCRIPTION

Hereinafter, the present invention will be described in detail by explaining embodiments of the invention with reference to the attached drawings.

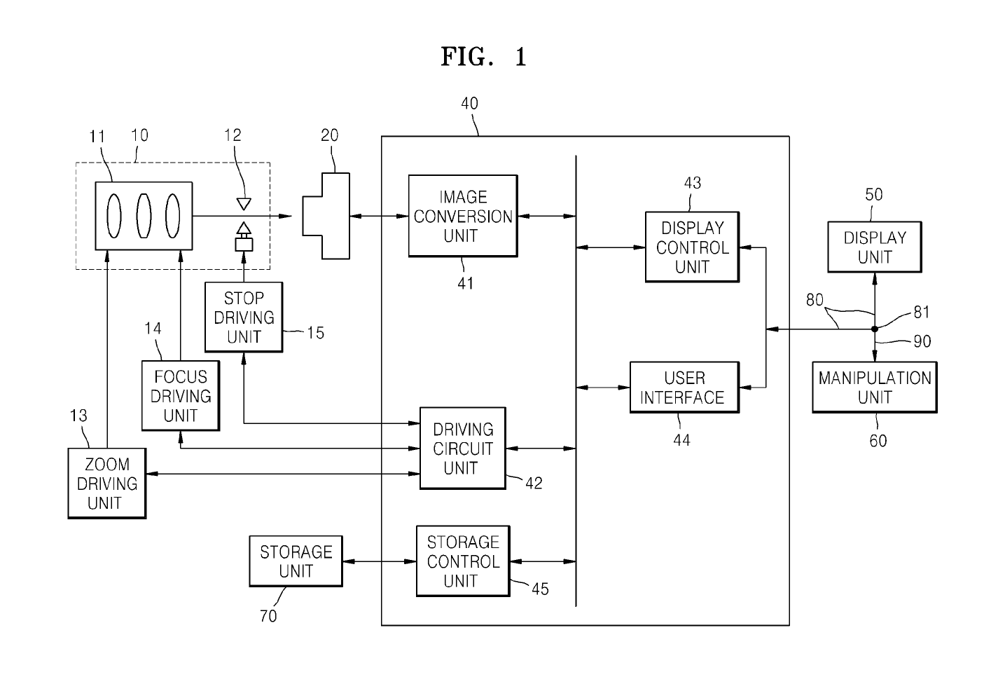

FIG. 1 is a block diagram showing elements of a photographing apparatus according to an embodiment of the present invention.

Referring to FIG. 1, the photographing apparatus includes a control unit 40 for controlling operations of other elements included in the photographing apparatus, a display unit 50 for displaying a captured image, a manipulation unit 60 for receiving an input of a user, a first flexible printed circuit board (FPCB) 80 for connecting the display unit 50 and the control unit 40 to each other, and a second

FPCB 90 for connecting the manipulation unit 60 and the first FPCB 80 to each other.

The control unit 40 is electrically connected to an imaging device 20, a zoom driving unit 13, a focus driving unit 14, a stop driving unit 15, the display unit 50, the manipulation unit 60, and a storage unit 70, and transmits and receives control signals to and from or processes data of the other elements in order to control their operations. The control unit 40 includes an image conversion unit 41, a driving circuit unit 42, a display control unit 43, a user interface 44, and a storage control unit 45 for controlling data in respect of the storage unit 70.

The control unit 40 may be implemented as a microchip or a circuit board including a microchip, and the elements included in the control unit 40 may be implemented as software installed in or circuits included in the control unit 40.

The imaging device 20 includes a photoelectric conversion device for converting image light passing through an optical system 10 into an image signal that is an electrical signal, e.g., a charge coupled device (CCD) or a complementary metal-oxide semiconductor (CMOS). A process of converting image light into an electrical signal may include sub-processes such as a process of converting the image light into an analog signal, and a process of converting the analog signal into a digital signal.

The optical system 10 disposed in front of the imaging device 20 includes a plurality of lenses 11 for forming external image light into an image on an imaging surface of the imaging device 20. The lenses 11 are spaced apart from each other by variable distances. A zoom ratio and focus of the optical system 10 may be adjusted by varying the distances between the lenses 11.

A stop 12 adjusts the intensity of light incident on the imaging device 20 when an image is captured. The stop 12 may be driven by the stop driving unit 15 controlled by the control unit 40.

Positions of the lenses 11 may be varied by the zoom driving unit 13 or the focus driving unit 14 having a driving means such as a zoom motor or a focus motor. The lenses 11 may include a zoom lens for magnifying or minifying an image of a subject, and a focus lens for adjusting focus on the subject. The zoom driving unit 13, the focus driving unit 14, and the stop driving unit 15 operate according to control signals received from the driving circuit unit 42 of the control unit 40.

The storage control unit 45 controls recording of image data onto the storage unit 70, and controls writing and reading of image data or setup information recorded on the storage unit 70. The storage unit 70 may be semiconductor memory such as synchronous dynamic random access memory (SDRAM) and may store data of a captured image.

The display unit 50 may be a display apparatus such as a liquid crystal display (LCD) or an organic light emitting display (OLED). The display unit 50 transmits and receives signals to and from the display control unit 43 of the control unit 40 according to a request of the user to allow the user to set a desired composition with regard to a subject to be photographed while viewing an image formed by the imaging device 20, or to check a captured image.

The manipulation unit 60 receives the user's manipulation. The manipulation unit 60 may be implemented as buttons or a jog dial for manipulating menus. The photographing apparatus may receive a signal of the manipulation unit 60 via the user interface 44 of the control unit 40. The user may select one of a plurality of images captured and displayed on the display unit 50 by manipulating the manipulation unit 60.

The first FPCB 80 has one end connected to the display unit 50 and another end connected to the control unit 40, and thus is disposed to enable signal transmission and reception between the display unit 50 and the control unit 40. An access unit 81 is disposed on one region of the first FPCB 80.

The second FPCB 90 has one end connected to the manipulation unit 60 and another end connected to the access unit 81 of the first FPCB 80, and thus is disposed to enable signal transmission and reception between the manipulation unit 60 and the control unit 40.

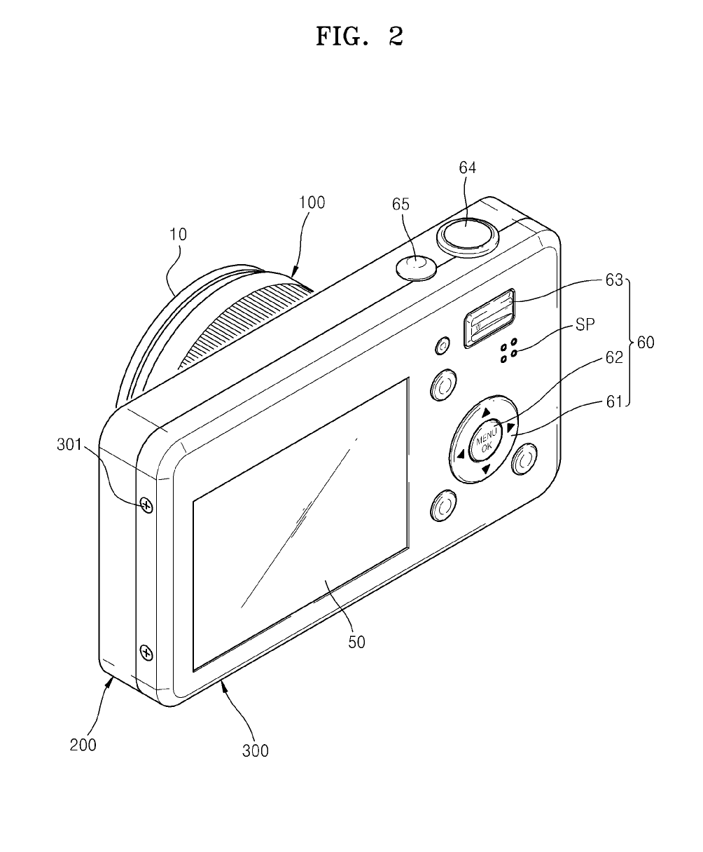

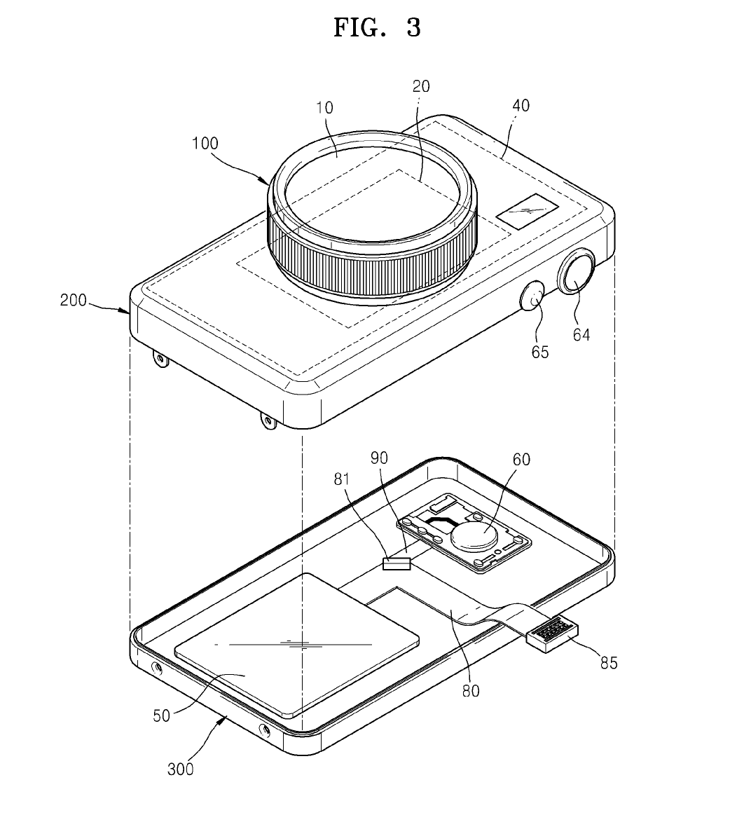

FIG. 2 is a perspective view showing an exterior of a photographing apparatus according to an embodiment of the present invention. FIG. 3 is a partially exploded perspective view of the photographing apparatus illustrated in FIG. 2.

Referring to FIGS. 2 and 3, the photographing apparatus includes a barrel unit 100 including the optical system 10, a first body unit 200 including the imaging device 20 and the control unit 40, and a second body unit 300 disposed in back of the first body unit 200 and including the display unit 50 and the manipulation unit 60.

The first body unit 200 may include on its upper portion a shutter release button 64 for opening or closing a shutter to expose the imaging device 20 to light for a predetermined period of time, and a power switch 65 for controlling power on/off.

The imaging device 20 and the control unit 40 are included in the first body unit 200, and the control unit 40 may be a microchip or a PCB including a microchip. The display unit 50 included in the second body unit 300 may be a display device such as an LCD or an OLED, and displays an image of a subject by receiving a signal converted by the image conversion unit 41 of the control unit 40 from an image formed by the imaging device 20, or displays an image stored in the storage unit 70. The manipulation unit 60 may include a plurality of key buttons such as a direction button 61, a menu button 62, and a zoom button 63. The manipulation unit 60 may execute various menus related to operations of the optical system 10 or the display unit 50 of the photographing apparatus.

The manipulation unit 60 may include all buttons or jog dials used by a user to manipulate elements of the photographing apparatus such as the shutter release button 64 and the power switch 65. However, in the current embodiment, the manipulation unit 60 includes only the direction button 61, the menu button 62, and the zoom button 63 disposed on the second body unit 300 of the photographing apparatus.

In general, the first and second body units 200 and 300 are separately manufactured and then are assembled by a coupling elements 301 such as screws. In this case, the display unit 50 and the manipulation unit 60 included in the second body unit 300 are respectively connected to the display control unit 43 and the user interface 44 of the control unit 40 of the first body unit 200 and thus transmit and receive signals to and from other elements included in the photographing apparatus.

In this case, in order to connect the display unit 50 and the manipulation unit 60 of the second body unit 300 to the control unit 40 of the first body unit 200, the first and second FPCBs 80 and 90 having flexibility and capable of achieving a compact size, a high density, and three-dimensional wirings are used.

The first and second FPCBs 80 and 90 may be manufactured by forming wirings by using copper (Cu) on a flexible polymer film formed of a dielectric such as polyimide or polyester, and forming a coverlay to cover the wirings.

In this case, the wirings may be formed on only one surface of the flexible polymer film, or may be formed on two surfaces of the flexible polymer film to achieve a three-dimensional structure of the wirings.

Also, when a large number of wirings should be formed, a multilayer FPCB formed by stacking a plurality of polymer films and forming wirings on each polymer film by using Cu may be used.

Referring to FIG. 3, the display unit 50, the manipulation unit 60, the first FPCB 80 connected to the display unit 50, and the second FPCB 90 connected to the manipulation unit 60 are disposed on an inner surface of the second body unit 300 that faces the first body unit 200.

One end of the first FPCB 80 may include an access element 85 connected to the control unit 40.

The access unit 81 configured to allow the first FPCB 80 to be connected to the second FPCB 90 is disposed on one region of the first FPCB 80.

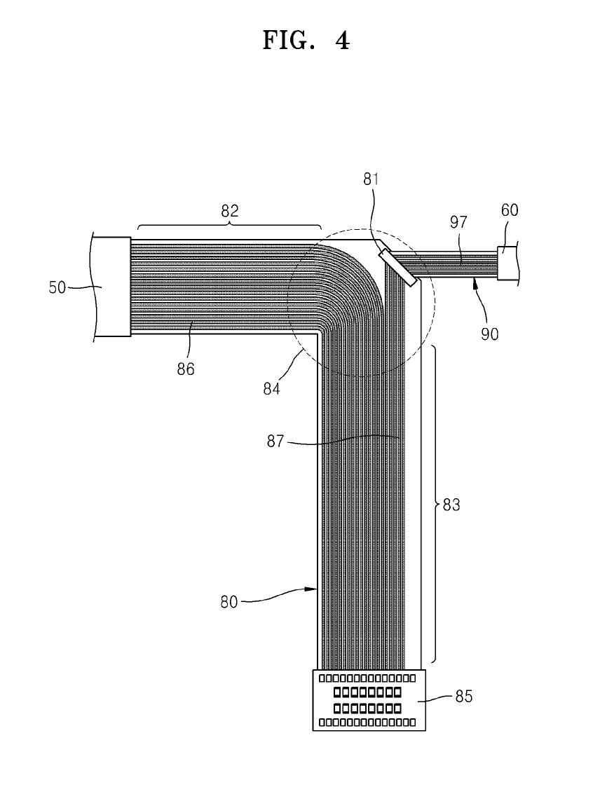

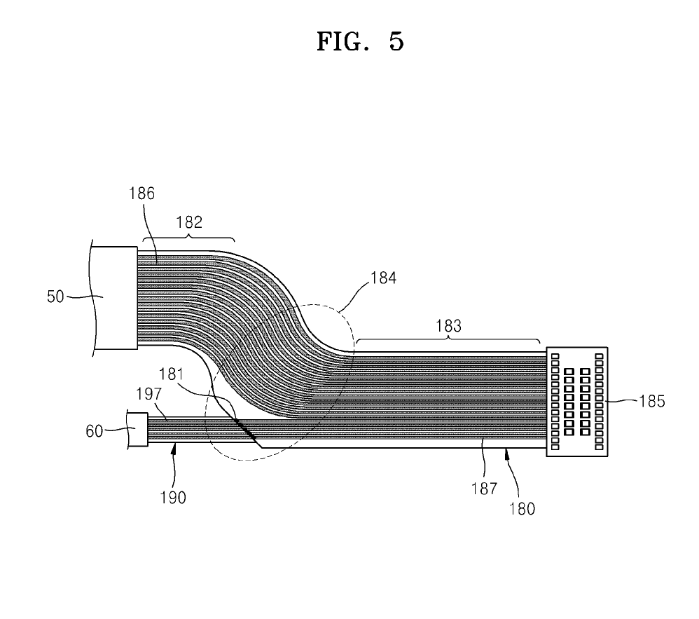

FIG. 4 is a plan view showing the structure of the first and second FPCBs 80 and 90 of the photographing apparatus illustrated in FIG. 3. FIG. 5 is a plan view showing a modified example of the first and second FPCBs 80 and 90 illustrated in FIG. 4.

Referring FIG. 4, the first FPCB 80 has one end connected to the display unit 50 and another end connected to the control unit 40, and includes the access unit 81 disposed on one region of the first FPCB 80, and the second FPCB 90 has one end connected to the manipulation unit 60 and another end connected to the access unit 81 of the first FPCB 80. The first FPCB 80 extends from the one end connected to the display unit 50 toward the other end connected to the control unit 40 to electrically connect the display unit 50 and the control unit 40 to each other, and includes a first wiring unit 86 including a data line for transmitting and receiving a signal, a ground line, and a power line, and a second wiring unit 87 extending from the access unit 81 toward the other end connected to the control unit 40 to electrically connect the control unit 40 and the second FPCB 90 to each other.

The first FPCB 80 includes a bent part 84 having an inner side along which the first wiring unit 86 curvedly extends. The access unit 81 is disposed on an outer corner of the bent part 84. The first wiring unit 86 curvedly extends along an inner side of the bent part 84 and the second wiring unit 87 is formed at an outer side of the first wiring unit 86.

The first FPCB 80 may include a first connection part 82 extending from the one end connected to the display unit 50 in one direction, and a second connection part 83 extending from the other end connected to the control unit 40 in a direction that forms an angle with the extending direction of the first connection part 82, and the bent part 84 connects the first and second connection parts 82 and 83 to each other.

When a lengthwise direction of the first connection part 82 forms an angle with a lengthwise direction of the second connection part 83, the first wiring unit 86 is bent to minimize stress of wirings. In the current embodiment, the first and second connection parts 82 and 83 are generally perpendicular to each other. As such, three-dimensional wirings may be easily achieved by using the first FPCB 80. One or a plurality of bent parts 84 may be formed.

In general, an FPCB includes a region where a wiring direction is changed and, in a process of manufacturing the region, a no-wiring region is formed on the FPCB.

In the current embodiment, a no-wiring region is formed on the bent part 84 of the first FPCB 80 and the access unit 81 is disposed on the bent part 84.

Accordingly, the second FPCB 90 having a relatively small number of wirings may be connected to the first FPCB 80 without forming an additional structure.

As such, the access element 85 of the first FPCB 80 may be connected to the control unit 40, and thus the display unit 50 and the manipulation unit 60 may be simultaneously connected to the control unit 40.

The display unit 50, as an LCD, has a complicated structure, performs a plurality of functions, and thus generally includes thirty to sixty wirings. The wirings include a power line, a data line, and a ground line.

On the other hand, the manipulation unit 60 generally includes ten or less wirings according to the number of key buttons disposed on a rear surface of the photographing apparatus.

Accordingly, since the second FPCB 90 connected to the manipulation unit 60 has a very small area in comparison to the first FPCB 80 connected to the display unit 50, the second FPCB 90 may be connected by disposing the access unit 81 as a connector on an extra space formed on the first FPCB 80 without using an additional component.

If the second FPCB 90 is connected to the access unit 81, a third wiring unit 97 formed on the second FPCB 90 may be electrically connected to the second wiring unit 87 formed on the second connection part 83 of the first FPCB 80, and thus signals may be transmitted and received between the manipulation unit 60 and the control unit 40. In this case, the second and third wiring units 87 and 97 correspond to each other. Ground lines may be connected to each other on the first FPCB 80.

Although the second wiring unit 87 is disposed at a side of and in parallel with the first wiring unit 86 in the current embodiment, if a multilayer FPCB is used, the first and second wiring units 86 and 87 may be disposed on different layers. Even in this case, the first and second wiring units 86 and 87 are substantially disposed in parallel with each other.

Also, the access unit 81 formed on the bent part 84 may be a connector. If the access unit 81 is a connector, the first and second FPCBs 80 and 90 are detachable from each other and thus the display unit 50 and the manipulation unit 60 may be separately aligned, thereby achieving convenience in configuration. In this case, an end portion of the second FPCB 90 may be inserted into the access unit 81. Alternatively, an end portion of the second FPCB 90 may include a coupling connector coupled to the access unit 81.

Referring to FIG. 5, an overall structure of FIG. 5 is the same as that of FIG. 4 except for the first FPCB 180 and the access unit 181.

The first FPCB 180 may also have various shapes other than the shape illustrated in FIG. 5, and may be of various types including a single side type in which wirings are formed on only one surface of a dielectric, a double side type in which wiring are formed on two surfaces of a dielectric, and a multilayer type in which wirings are formed on multiple layers.

The access unit 181 may include a pad formed on one end of a second wiring unit 187, and an access layer coated on the pad. The access layer may be formed of solder or a conductive adhesive such as an anisotropic conductive film (ACF).

The above descriptions are provided in relation to a photographing apparatus but are also applicable to any electronic device including a plurality of modules that are independent systems for performing different functions.

The electronic device may include a first module, a second module spaced apart from the first module, a third module for transmitting and receiving signals to and from the first and second modules, a first FPCB connected to the first and third modules and including an access unit on one region of the first FPCB, and a second FPCB connected to the second module and the access unit of the first FPCB.

A photographing apparatus and an electronic device according to the present invention may have a simple manufacturing process, a low manufacturing cost, a compact size, and a space-saving structure by improving the structure of FPCBs.

The device described herein may comprise a processor, a memory for storing program data and executing it, a permanent storage such as a disk drive, a communications port for handling communications with external devices, and user interface devices, including a touch panel, keys, buttons, etc. When software modules or algorithms are involved, these software modules may be stored as program instructions or computer readable codes executable on the processor on a computer-readable non-transitory medium. Examples of the computer readable recording medium include magnetic storage media (e.g., ROM, floppy disks, hard disks, etc.), and optical recording media (e.g., CD-ROMs, DVDs, etc.). The computer readable recording medium can also be distributed over network coupled computer systems so that the computer readable code is stored and executed in a distributed fashion. This media can be read by a computer, stored in the memory, and executed by the processor.

All references, including publications, patent applications, and patents, cited herein are hereby incorporated by reference to the same extent as if each reference were individually and specifically indicated to be incorporated by reference and were set forth in its entirety herein.

For the purposes of promoting an understanding of the principles of the invention, reference has been made to the preferred embodiments illustrated in the drawings, and specific language has been used to describe these embodiments. However, no limitation of the scope of the invention is intended by this specific language, and the invention should be construed to encompass all embodiments that would normally occur to one of ordinary skill in the art.

The present invention may be described in terms of functional block components and various processing steps. Such functional blocks may be realized by any number of hardware and/or software components configured to perform the specified functions. For example, the present invention may employ various integrated circuit components, e.g., memory elements, processing elements, logic elements, look-up tables, and the like, which may carry out a variety of functions under the control of one or more microprocessors or other control devices. Similarly, where the elements of the present invention are implemented using software programming or software elements the invention may be implemented with any programming or scripting language such as C, C++, Java, assembler, or the like, with the various algorithms being implemented with any combination of data structures, objects, processes, routines, or other programming elements. Functional aspects may be implemented in algorithms that execute on one or more processors. Furthermore, the present invention could employ any number of conventional techniques for electronics configuration, signal processing and/or control, data processing, and the like. The words “mechanism”, “element”, “means”, and “configuration” are used broadly and are not limited to mechanical or physical embodiments, but can include software routines in conjunction with processors, etc.

The particular implementations shown and described herein are illustrative examples of the invention and are not intended to otherwise limit the scope of the invention in any way. For the sake of brevity, conventional electronics, control systems, software development, and other functional aspects of the systems may not be described in detail. Furthermore, the connecting lines, or connectors shown in the various figures presented are intended to represent exemplary functional relationships and/or physical or logical couplings between the various elements. It should be noted that many alternative or additional functional relationships, physical connections, or logical connections may be present in a practical device.

Moreover, no item or component is essential to the practice of the invention unless the element is specifically described as “essential” or “critical”.

The use of the terms “a” and “an” and “the” and similar referents in the context of describing the invention (especially in the context of the following claims) are to be construed to cover both the singular and the plural. Furthermore, recitation of ranges of values herein are merely intended to serve as a shorthand method of referring individually to each separate value falling within the range, unless otherwise indicated herein, and each separate value is incorporated into the specification as if it were individually recited herein. Finally, the steps of all methods described herein can be performed in any suitable order unless otherwise indicated herein or otherwise clearly contradicted by context. The present invention is not limited to the described order of the steps. The use of any and all examples, or exemplary language (e.g., “such as”) provided herein, is intended merely to better illuminate the invention and does not pose a limitation on the scope of the invention unless otherwise claimed. Numerous modifications and adaptations will be readily apparent to those of ordinary skill in the art without departing from the spirit and scope of the present invention.

What is claimed is:

1. A photographing apparatus comprising:
a display unit that displays an image;
a manipulation unit spaced apart from the display unit;
a control unit that transmits and receives signals to and from the manipulation unit and the display unit;
a first flexible printed circuit board (FPCB) having one end connected to the display unit, and another end connected to the control unit, and comprising an access unit on one region of the first FPCB; and
a second FPCB having one end connected to the manipulation unit, and another end connected to the access unit of the first FPCB.

2. The photographing apparatus of claim 1, further comprising:
an imaging device for converting an optical image of a subject into an electrical signal;
wherein an image formed by the imaging device is displayable on the display unit.

3. The photographing apparatus of claim 1, wherein the first FPCB comprises:
a first wiring unit extending from the one end toward the other end to electrically connect the display unit and the control unit to each other; and
a second wiring unit extending from the access unit toward the other end to electrically connect the control unit and the second FPCB to each other.

4. The photographing apparatus of claim 3, wherein:
the first FPCB comprises a bent part; and
the access unit is disposed on the bent part.

5. The photographing apparatus of claim 4, wherein the access unit is disposed on an outer corner of the bent part.

6. The photographing apparatus of claim 4, wherein:
the first wiring unit curvedly extends along an inner side of the bent part; and
the second wiring unit is formed at an outer side of the first wiring unit.

7. The photographing apparatus of claim 4, wherein:
the first FPCB comprises a plurality of layers; and
at least a portion of the first wiring unit and the second wiring unit are disposed on different layers.

8. The photographing apparatus of claim 4, wherein:
the first FPCB comprises:
a first connection part extending from the one end in one direction; and
a second connection part extending from the other end in a direction that forms an angle with the extending direction of the first connection part; and wherein
the bent part connects the first and second connection parts to each other.

9. The photographing apparatus of claim 1, wherein the access unit is a connector.

10. The photographing apparatus of claim 9, wherein the second FPCB comprises a coupling connector coupled to the connector.

11. The photographing apparatus of claim 1, wherein the access unit comprises:
a pad formed on the one end of the second wiring unit; and
an access layer coated on the pad.

12. The photographing apparatus of claim 11, wherein the access layer is formed of solder or a conductive adhesive.

13. The photographing apparatus of claim 1, wherein a number of wirings formed on the first FPCB is greater than a number of wirings formed on the second FPCB.

14. An electronic device comprising:
a first module;
a second module spaced apart from the first module;
a third module that transmits and receives signals to and from the first and second modules;
a first flexible printed circuit board (FPCB) having one end connected to the first module, and another end connected to the third module, and comprising an access unit on one region of the first FPCB; and
a second FPCB having one end connected to the second module, and another end connected to the access unit of the first FPCB.

15. The electronic device of claim 14, wherein a number of wirings formed on the first FPCB is greater than a number of wirings formed on the second FPCB.

16. The electronic device of claim 14, wherein:
the first FPCB comprises a bent part; and
the access unit is disposed on the bent part.

17. The electronic device of claim 14, wherein the access unit is disposed on an outer corner of the bent part.
